(19) United States
(12) Patent Application Publication
(10) Pub. No.: US 2023/0047907 A1
(43) Pub. Date: Feb. 16, 2023

(54) LIGHT EMITTING DEVICE, PHOTOELECTRIC CONVERSION DEVICE, ELECTRONIC EQUIPMENT, ILLUMINATION DEVICE, AND MOVING BODY

(71) Applicant: CANON KABUSHIKI KAISHA, Tokyo (JP)

(72) Inventors: Daichi Seto, Kanagawa (JP); Shinya Igarashi, Kanagawa (JP); Tetsuro Yamamoto, Kanagawa (JP)

(21) Appl. No.: 17/881,719

(22) Filed: Aug. 5, 2022

(30) Foreign Application Priority Data
Aug. 12, 2021 (JP) 2021-131743

(51) Int. Cl. H01L 27/32

(52) U.S. Cl. CPC H01L 27/3253; H01L 27/3276

(57) ABSTRACT

A light emitting device has a structure in which a first substrate and a second substrate are stacked. The device includes a plurality of light emitting elements, and a driving circuit configured to drive the plurality of light emitting elements. Part of the driving circuit is arranged in the first substrate, and another part of the driving circuit is arranged in the second substrate.

### BACKGROUND OF THE INVENTION

### Field of the Invention

The present invention relates to a light emitting device, a photoelectric conversion device, an electronic equipment, an illumination device, and a moving body.

### Description of the Related Art

There is known a semiconductor device having a structure in which a substrate on which a plurality of light emitting elements are arranged and a substrate on which driving circuits for driving the plurality of light emitting elements are arranged are stacked. A semiconductor device described in Japanese Patent Laid-Open No. 2018-174246 includes the first substrate with the first transistor for driving a light receiving element and the second substrate with the second transistor for driving a light emitting element. The first substrate includes the light emitting element, the light receiving element, and a through electrode that transmits a driving signal of the light emitting element from the second substrate through the first substrate.

In the structure in which the substrate on which the plurality of light emitting elements are arranged and the substrate on which the driving circuits for driving the plurality of light emitting elements are arranged are stacked, it is possible to implement high integration without miniaturizing the light emitting elements and the driving circuits. However, the arrangement in which the driving circuits are integrated in one substrate has limitation for increasing the density of the light emitting elements.

### SUMMARY OF THE INVENTION

The present invention provides a technique advantageous in increasing the density of light emitting elements.

According to one aspect of the present invention, there is provided a light emitting device having a structure in which a first substrate and a second substrate are stacked, comprising: a plurality of light emitting elements; and a driving circuit configured to drive the plurality of light emitting elements, wherein part of the driving circuit is arranged in the first substrate, and another part of the driving circuit is arranged in the second substrate.

Further features of the present invention will become apparent from the following description of exemplary embodiments with reference to the attached drawings.

### BRIEF DESCRIPTION OF THE DRAWINGS

FIG. 1 is a schematic view showing the arrangement of a light emitting device according to the first embodiment;

FIG. 2 is circuit diagram exemplifying the circuit arrangement of one pixel of the light emitting device according to the first embodiment;

FIG. 3 is a view exemplifying the sectional structure of one pixel of the light emitting device according to the first embodiment;

FIG. 4 is a view exemplifying the sectional structure of the light emitting device according to the first modification of the first embodiment;

FIG. 5 is a view exemplifying the sectional structure of the light emitting device according to the second modification of the first embodiment;

FIG. 6 is a circuit diagram exemplifying the circuit arrangement of the light emitting device according to the third modification of the first embodiment;

FIG. 7 is a circuit diagram exemplifying the circuit arrangement of a light emitting device according to the first modification of the second embodiment;

FIG. 8 is a view exemplifying the sectional structure of one pixel of the light emitting device according to the second embodiment;

FIG. 9 is a circuit diagram exemplifying the circuit arrangement of the light emitting device according to a modification of the second embodiment;

FIG. 10 is a view exemplifying the sectional structure of the light emitting device according to the modification of the second embodiment;

FIG. 11 is a circuit diagram exemplifying the circuit arrangement of one pixel of a light emitting device according to the third embodiment;

FIG. 12 is a circuit diagram exemplifying the circuit arrangement of one pixel of a light emitting device according to the fourth embodiment;

FIG. 13 is a circuit diagram exemplifying the circuit arrangement of one pixel of a light emitting device according to the fifth embodiment;

FIG. 14 is a circuit diagram exemplifying the circuit arrangement of one pixel of a light emitting device according to the sixth embodiment;

FIG. 15 is a circuit diagram exemplifying the circuit arrangement of one pixel of a light emitting device according to the seventh embodiment;

FIG. 16 is a view exemplifying the sectional structure of one pixel of the light emitting device according to the seventh embodiment;

FIG. 17A is a schematic sectional view showing an example of a pixel of a display device according to one application example;

FIG. 17B is a schematic sectional view showing an example of a display device using an organic light emitting element according to one application example;

FIG. 18 is a schematic view showing an example of a display device according to one application example;

FIG. 19A is a schematic view showing an example of an image capturing device according to one application example;

FIG. 19B is a schematic view showing an example of an electronic equipment according to one application example;

FIG. 20A is a schematic view showing an example of a display device according to one application example;

FIG. 20B is a schematic view showing an example of a display device according to one application example;

FIG. 21A is a schematic view showing an example of an illumination device according to one application example;

FIG. 21B is a schematic view showing an example of an automobile having a vehicle lighting appliance according to one application example;

FIG. 22A is a schematic view showing an example of a wearable device according to one application example; and

FIG. 22B is a schematic view showing an example of a wearable device according to one application example.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

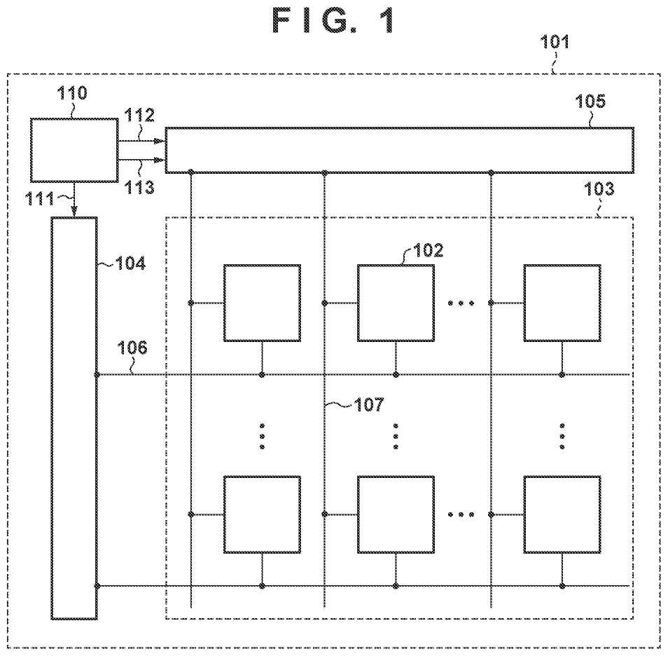

FIG. 1 schematically shows the circuit arrangement of a light emitting device according to the first embodiment. A light emitting device 101 according to the first embodiment can include a vertical scanning circuit 104, a signal output circuit 105, and a control unit 110. A pixel array 103 can include a plurality of pixels 102 arranged to form a plurality of rows and a plurality of columns. In the following description, a row direction indicates a direction parallel to the plurality of rows and a column direction indicates a direction parallel to the plurality of columns. The control unit 110 can generate a control signal for controlling the vertical scanning circuit 104 and a vertical scanning control signal 111. For example, the control unit 110 can supply the vertical scanning control signal 111 to the vertical scanning circuit 104, and supply a signal output control signal 112 and image data 113 to the signal output circuit 105.

The vertical scanning circuit 104 can be configured to drive a plurality of scanning lines 106 extending in the row direction. In accordance with the vertical scanning control signal 111, the vertical scanning circuit 104 outputs a write control signal to each scanning line 106. Note that the output of the write control signal means activation of the write control signal. In accordance with the signal output control signal 112, the signal output circuit 105 can receive the image data 113 sequentially sent from the control unit 110. The signal output circuit 105 generates a voltage signal (to be referred to as Vsig hereinafter) as a luminance signal corresponding to the value of the image data 113 by D/A-converting the image data 113, and outputs the voltage signal to each signal line 107. At each of the intersection points of the scanning lines 106 and the signal lines 107, the pixel 102 is arranged, and each scanning line 106 and each signal line 107 are connected to the corresponding pixel 102. The pixel 102 emits light with luminance corresponding to the signal level of Vsig supplied to itself. Note that FIG. 1 exemplifies the pixel array 103 including pixels of 3 columns in the horizontal direction and 2 rows in the vertical direction but the number of pixels is not limited to this. Even if the number of pixels is exemplified in other drawings, the number of pixels is not limited to that.

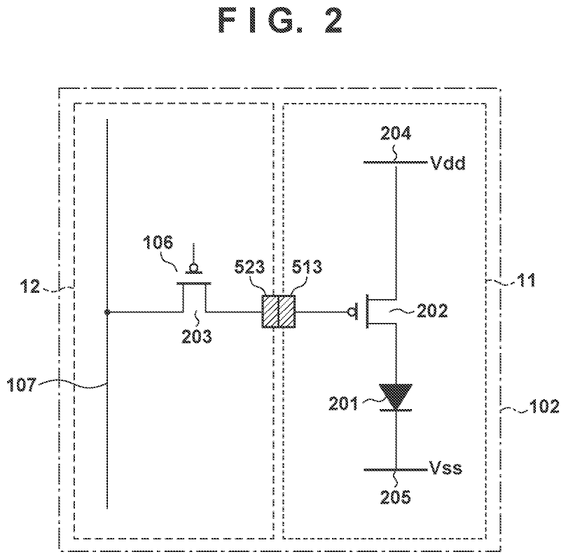

FIG. 2 exemplifies the circuit arrangement of one pixel 102 of the light emitting device 101 shown in FIG. 1. As exemplified in FIG. 2, each pixel 102 can include a light emitting element 201 and a plurality of elements for driving the light emitting element 201. The plurality of elements of each pixel 102 can form a unit driving circuit. It can be understood that an aggregate of the plurality of elements of the plurality of pixels 102 forming the pixel array 103 forms a driving circuit that drives the plurality of light emitting elements 201 of the pixel array 103. The plurality of elements of each pixel 102 can include a plurality of active elements. The plurality of elements of each pixel 102 may include a plurality of active elements and at least one passive element (for example, a capacitive element). In one example, the plurality of elements of each pixel 102 can include a driving transistor 202 that drives the light emitting element 201, and a write transistor 203 that writes a signal in a write node including the gate of the driving transistor.

The light emitting device 101 can have a structure in which a first substrate 11 and a second substrate 12 are stacked on each other. The light emitting device 101 may have an arrangement in which three or more substrates are stacked on each other. The light emitting device 101 may be configured as a display device, for example, an organic EL (Organic Electroluminescent) display device. In this case, the light emitting element 201 can include an organic layer with a light emitting layer between an anode and a cathode. The organic layer may include at least one of a hole injection layer, a hole transport layer, an electron injection layer, and an electron transport layer in addition to the light emitting layer. An example in which the driving transistor 202 is connected to the anode of the light emitting element 201 and all transistors are p-type transistors will be described below but the light emitting device according to the present invention is not limited to this. The polarity and conductivity types may all be reversed. For example, the driving transistor may be a p-type transistor and the remaining transistors may be n-type transistors, and supplied potentials and connection can be changed appropriately in accordance with the polarity and conductive type.

As a practical arrangement example, one (the drain in this example) of the source and drain of the driving transistor 202 is connected to the first electrode (the anode in this example) of the light emitting element 201. The other (the source in this example) of the source and drain of the driving transistor 202 is connected to a first voltage line (to be referred to as Vdd hereinafter) 204. The second electrode (the cathode in this example) of the light emitting element 201 is connected to a second voltage line (to be referred to as Vss hereinafter) 205.

The driving transistor 202 supplies a current from the Vdd 204 to the Vss 205 via the light emitting element 201, thereby causing the light emitting element 201 to emit light. More specifically, the driving transistor 202 supplies, to the light emitting element 201, a current corresponding to the voltage signal Vsig written in the write node via the signal line 107. The driving transistor 202 thus current-drives the light emitting element 201 to emit light.

One of the source and drain of the write transistor 203 can electrically be connected to the write node including the gate of the driving transistor 202. The other of the source and drain of the write transistor 203 can electrically be connected to the signal line 107 and the gate of the write transistor 203 can electrically be connected to the scanning line 106.

The light emitting element 201 can be arranged on a second surface S2 of the first substrate 11, the driving transistor 202 can be arranged in the first substrate 11, and the Vdd 204 and the Vss 205 can be arranged in a first wiring structure 512. From another viewpoint, the light emitting element 201, the driving transistor 202, the Vdd 204, and the Vss 205 can be arranged in the first structure formed from the first substrate 11 and the first wiring structure 512. The write transistor 203 can be arranged in the second substrate 12, and the scanning line 106 and the signal line 107 can be arranged in the second wiring structure 522. From another viewpoint, the write transistor 203, the scanning line 106, and the signal line 107 can be arranged in the second structure formed from the second substrate 12 and the second wiring structure 522. A bonding portion 513 can electrically be connected to the gate of the driving transistor 202 arranged in the first substrate 11 via a conductive path (for example, a wiring pattern or plug).

A bonding portion 523 can electrically be connected to the source of the write transistor 203 arranged in the second substrate 12 via a conductive path (for example, a wiring pattern or plug). The bonding portions 513 and 523 can be bonded to each other. The bonding portions 513 and 523 can be made of copper (Cu) and can be bonded by Cu—Cu bonding. However, the bonding method is not limited to Cu—Cu bonding.

The write transistor 203 is rendered conductive in response to the control signal applied to the gate. This allows the write transistor 203 to write, in the write node of the pixel 102, the voltage signal Vsig corresponding to display data supplied from the signal output circuit 105 via the signal line 107. The voltage signal Vsig written in the write node is applied to the gate of the driving transistor 202. Note that in any of the transistors, a back gate voltage can be the voltage of the Vdd 204.

If the light emitting element 201 is formed by an organic EL element, the current flowing through the driving transistor 202 can depend on the voltage signal Vsig. With this current, the capacitance between the first electrode (the anode in this example) and the second electrode (the cathode in this example) of the light emitting element 201 is charged to a potential corresponding to the voltage signal Vsig, and a current corresponding to the potential flows through the light emitting element 201. Thus, the light emitting element 201 emits light with luminance corresponding to the voltage signal Vsig.

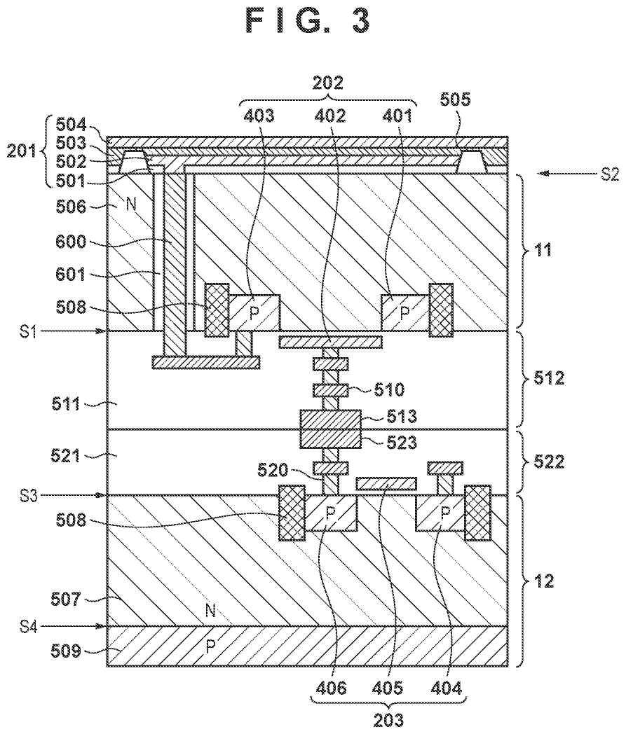

FIG. 3 schematically shows the sectional structure of one pixel 102 of the light emitting device 101 according to the first embodiment. The light emitting device 101 can have a structure in which the first substrate 11 and the second substrate 12 are stacked on each other. Each of the first substrate 11 and the second substrate 12 can be a semiconductor substrate, for example, a silicon substrate made of silicon (Si). The first substrate 11 includes a first surface S1 and the second surface S2 which are opposing faces, and the second substrate 12 includes a third surface S3 and a fourth surface S4 which are opposing faces. The first wiring structure 512 can be arranged to contact the first surface S1, and the second wiring structure 522 can be arranged to contact the third surface S3. The first wiring structure 512 and the second wiring structure 522 can be connected to each other. The plurality of light emitting elements 201 can be arranged on the second surface S2 of the first substrate 11. At least part of the driving transistor 202 (first element) can be arranged between the first surface S1 and the first wiring structure 512. At least part of the write transistor 203 (second element) can be arranged between the third surface S3 and the second wiring structure 522.

The first wiring structure 512 can include a plurality of stacked conductive paths (wiring patterns or plugs) 510, and an interlayer insulating film 511 arranged to insulate the plurality of conductive paths 510. The second wiring structure 522 can include a plurality of stacked conductive paths (wiring patterns or plugs) 520, and an interlayer insulating film 521 arranged to insulate the plurality of conductive paths 520. Each of the conductive paths 510 and 520 can be made of a wiring material such as copper (Cu), tungsten (W), or aluminum (Al). The conductive paths 510 and 520 can be formed by bonding the bonding portions 513 and 523 to each other. The bonding portions 513 and 523 can electrically be connected by, for example, Cu—Cu bonding.

An n-type well layer 506 can be arranged in the first substrate 11. Part of the driving transistor 202 can be arranged between the first substrate 11 and the first wiring structure 512. More specifically, p-type diffusion regions 401 and 403 of the driving transistor 202 can be arranged in the first substrate 11, and a gate 402 of the driving transistor 202 can be arranged on the first surface S1 of the first substrate 11 via a gate insulating film. The driving transistor 202 can be formed by, for example, a general CMOS process. An n-type well layer 507 and a p-type semiconductor layer 509 can be arranged in the second substrate 12. Part of the write transistor 203 is arranged between the second substrate 12 and the second wiring structure 522. More specifically, p-type diffusion regions 404 and 406 of the write transistor 203 can be arranged in the second substrate 12, and a gate 405 of the write transistor 203 can be arranged on the third surface S3 of the second substrate 12 via a gate insulating film. The write transistor 203 can be formed by a general CMOS process. The p-type diffusion regions 401 and 403 of the first substrate 11 may be different from the p-type diffusion regions 404 and 406 of the second substrate 12 in at least one of the density and the depth.

In the first substrate 11, for example, a conductive plug 600 can be arranged as a conductive path penetrating the first substrate 11. In one example, a through hole can be formed in the first substrate 11, and the conductive plug 600 can be arranged in the through hole via an insulating film 601. The conductive plug 600 can be made of, for example, copper (Cu), tungsten (W), or aluminum (Al). An STI (Shallow Trench Isolation) 508 can be arranged at the boundary between the pixels in the first substrate 11. The STI (Shallow Trench Isolation) 508 can also be arranged at the boundary between the pixels in the second substrate 12.

An insulating film 501 can be arranged on the second surface S2 of the first substrate 11. The light emitting element 201 can be arranged on the insulating film 501. The light emitting element 201 can include, for example, a lower electrode 502, an organic EL film (light emitting layer) 503, and an upper electrode 504. The lower electrode 502 can be made of a metal material. The upper electrode 504 can be formed by a transparent electrode that transmits light. In one example, the lower electrode 502 serves as the anode and the upper electrode 504 serves as the cathode but they may be reversed. The light emitting element 201 can emit light in accordance with the driving signal transmitted via the conductive plug 600.

The light emitting device 101 can include the first substrate 11 in which the driving transistor 202 that drives the light emitting element 201 is arranged and the second substrate 12 in which the write transistor 203 is arranged. The light emitting element 201 can be arranged on the second surface S2 of the first substrate 11, and the driving transistor 202 and the light emitting element 201 can electrically be connected by the conductive plug 600 penetrating the first substrate 11. In this arrangement, an area occupied by the transistor in each of the first substrate 11 and the second substrate 12 can be decreased. Therefore, the light emitting device 101 according to the first embodiment is advantageous in arranging the light emitting elements at a high density without reducing the size of each transistor. Furthermore, the first embodiment is advantageous in increasing the resolution when the light emitting device 101 is implemented as a display device.

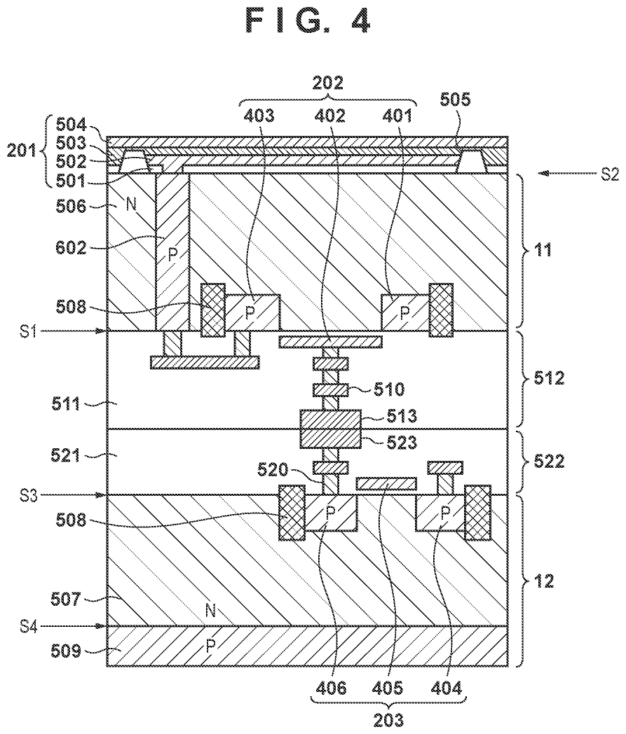

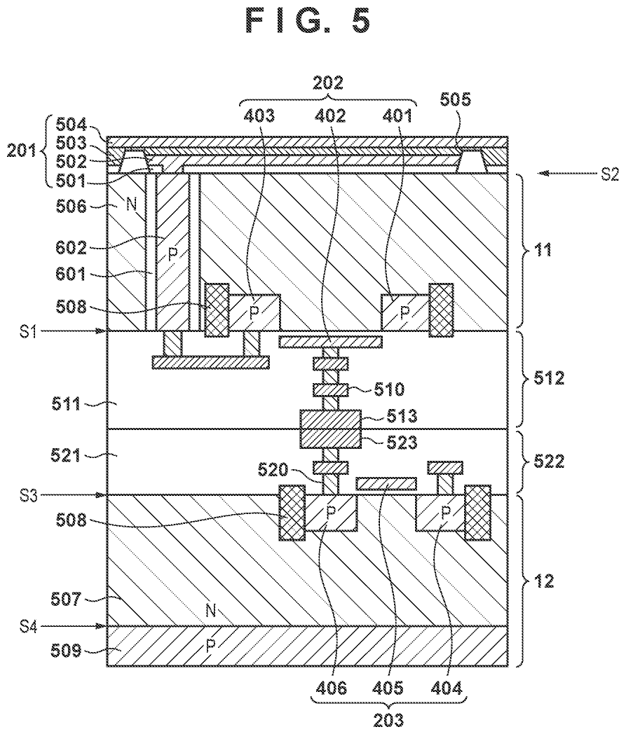

FIG. 4 exemplifies a sectional structure according to the first modification of the first embodiment. Matters not mentioned in the first modification can comply with the first embodiment. In the first modification, an impurity semiconductor region, more specifically, a p-type diffusion region 602 is provided as a conductive path penetrating the first substrate 11. FIG. 5 shows a sectional structure according to the second modification of the first embodiment. Matters not mentioned in the second modification can comply with the first embodiment. In the second modification, an impurity semiconductor region, more specifically, a p-type diffusion region 602 is provided as a conductive path penetrating the first substrate 11. In addition, in the second modification, an insulating film 601 is provided to surround the p-type diffusion region 602. The impurity semiconductor region may be formed by an n-type diffusion region.

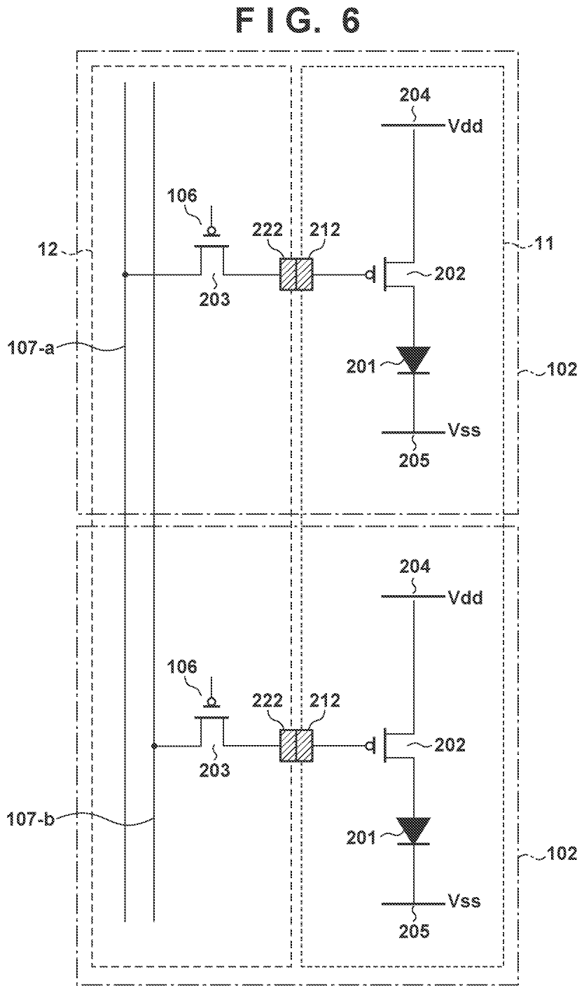

FIG. 6 exemplifies a circuit arrangement according to the third modification of the first embodiment. Matters not mentioned in the third modification can comply with the first embodiment or the first or second modification. In the third modification, a plurality of signal lines, for example, two signal lines 107-a and 107-b extending in the column direction are provided for each column of the pixel array 103. The write transistors 203 and the two signal lines 107-a and 107-b provided in each column can be arranged in the second wiring structure 522. This arrangement is advantageous in arranging the light emitting elements at a high density without reducing the size of each transistor. Furthermore, the third modification is advantageous in increasing the resolution and improving the frame rate when the light emitting device 101 is implemented as a display device.

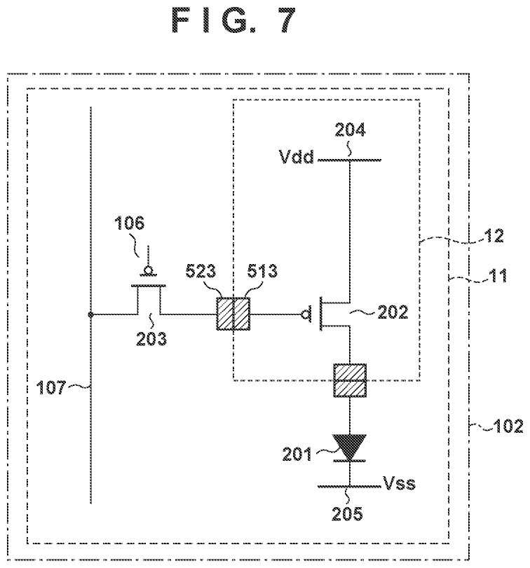

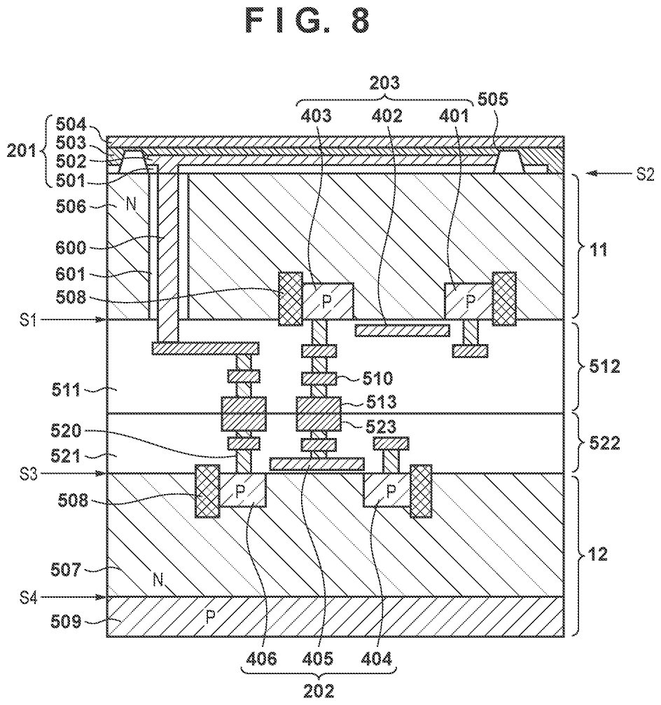

FIG. 7 exemplifies the circuit arrangement of a pixel 102 of a light emitting device 101 according to the second embodiment. FIG. 8 exemplifies the sectional structure of the pixel 102 of the light emitting device 101 according to the second embodiment. Matters not mentioned in the second embodiment can comply with one of the first embodiment and its modifications. In the second embodiment, a light emitting element 201 can be arranged on a second surface S2 of a first substrate 11, a write transistor 203 can be arranged in the first substrate 11, and a scanning line 106, a signal line 107, and a Vss 205 can be arranged in a first wiring structure 512. From another viewpoint, the light emitting element 201, the write transistor 203, the scanning line 106, the signal line 107, and the Vss 205 can be arranged in the first structure formed from the first substrate 11 and the first wiring structure 512. Furthermore, in the second embodiment, a driving transistor 202 can be arranged in a second substrate 12, and a Vdd 204 can be arranged in a second wiring structure 522. From another viewpoint, the driving transistor 202 and the Vdd 204 can be arranged in the second structure formed from the second substrate 12 and the second wiring structure 522.

A bonding portion 523 can electrically be connected to a gate 405 of the driving transistor 202 arranged in the second substrate 12 via a conductive path (for example, a wiring pattern or plug). A bonding portion 513 can electrically be connected to the source of the write transistor 203 arranged in the first substrate 11 via a conductive path (for example, a wiring pattern or plug). The bonding portions 513 and 523 can be bonded to each other. The bonding portions 513 and 523 can be made of copper (Cu) and can be bonded by Cu—Cu bonding. However, the bonding method is not limited to Cu—Cu bonding.

Part of the write transistor 203 can be arranged between the first substrate 11 and the first wiring structure 512. More specifically, p-type diffusion regions 401 and 403 of the write transistor 203 can be arranged in the first substrate 11, and a gate 402 of the write transistor 203 can be arranged on a first surface S1 of the first substrate 11 via a gate insulating film. The write transistor 203 can be formed by, for example, a general CMOS process. Part of the driving transistor 202 can be arranged between the second substrate 12 and the second wiring structure 522. More specifically, p-type diffusion regions 404 and 406 of the driving transistor 202 can be arranged in the second substrate 12, and a gate 405 of the driving transistor 202 can be arranged on a third surface S3 of the second substrate 12 via a gate insulating film. The driving transistor 202 can be formed by a general CMOS process. The p-type diffusion regions 401 and 403 of the first substrate 11 may be different from the p-type diffusion regions 404 and 406 of the second substrate 12 in at least one of the density and the depth.

In the above-described arrangement, an area occupied by the transistor in each of the first substrate 11 and the second substrate 12 can be decreased. Therefore, the light emitting device 101 according to the second embodiment is advantageous in arranging the light emitting elements at a high density without reducing the size of each transistor. Furthermore, the second embodiment is advantageous in increasing the resolution when the light emitting device 101 is implemented as a display device.

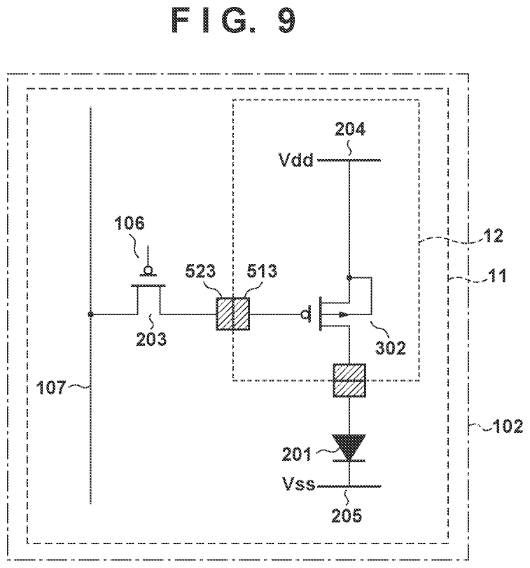

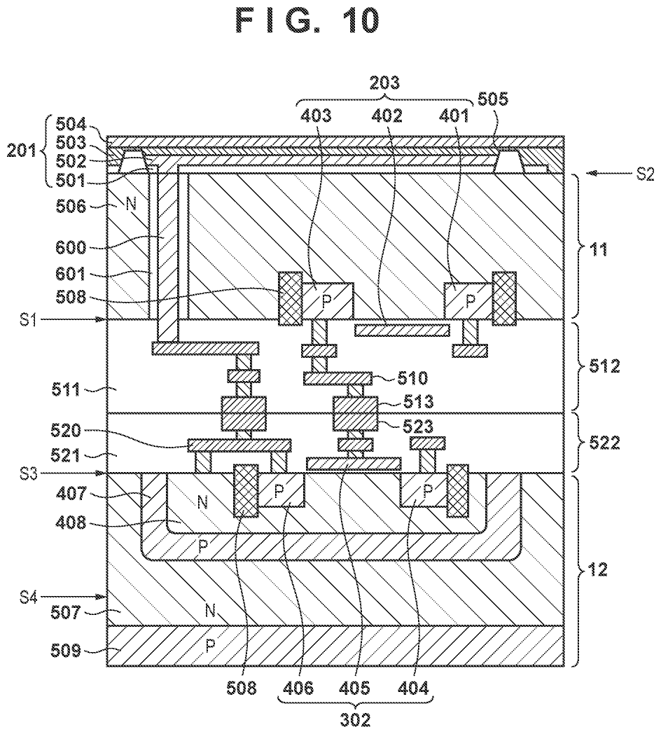

FIG. 9 shows the circuit arrangement of the pixel 102 of the light emitting device 101 according to a modification of the second embodiment. FIG. 10 shows the sectional structure of the pixel 102 of the light emitting device 101 according to the modification of the second embodiment. Matters not mentioned in the modification can comply with the second embodiment.

In this modification, the driving transistor 202 of the second embodiment is replaced by a driving transistor 302. The back gate of the driving transistor 302 is self-biased. The source and back gate of the driving transistor 302 are electrically connected to the Vdd 204. An n-type well layer 507 and a p-type semiconductor layer 509 can be arranged in the second substrate 12. A p-type semiconductor region 407 can be arranged inside the n-type well layer 507 and an n-type well layer 408 can be arranged inside the p-type semiconductor region 407. The n-type well layer 507 and the n-type well layer 408 can be separated by the p-type semiconductor region 407. Part of the driving transistor 302 using the n-type well layer 408 can be arranged between the second substrate 12 and the second wiring structure 522. More specifically, p-type diffusion regions 404 and 406 of the driving transistor 302 can be arranged in the second substrate 12, and a gate 405 of the driving transistor 302 can be arranged on the third surface S3 of the second substrate 12 via a gate insulating film. The driving transistor 302 can be formed by a general CMOS process. The p-type diffusion regions 401 and 403 of the first substrate 11 may be different from the p-type diffusion regions 404 and 406 of the second substrate 12 in at least one of the density and the depth.

In the light emitting device 101 according to the modification of the second embodiment, the driving transistor 302 whose back gate is self-biased is arranged in the second substrate 12, and it is thus possible to suppress characteristic variations caused by manufacturing variations of the transistors. This is advantageous in suppressing the light amount variations in the plurality of pixels 102 of the light emitting device 101.

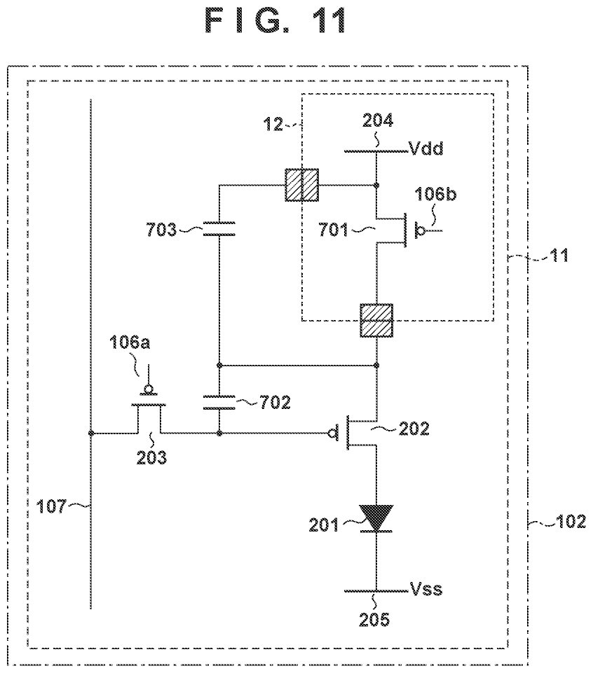

FIG. 11 exemplifies the circuit arrangement of one pixel 102 of a light emitting device 101 according to the third embodiment. Matters not mentioned in the third embodiment can comply with one of the first and second embodiments and their modifications. In the third embodiment, each pixel 102 can include a light emitting element 201, a driving transistor 202, a write transistor 203, a Vdd 204, a Vss 205, a light emission control transistor 701, a first capacitive element 702, and a second capacitive element 703. In the third embodiment, each pixel 102 can further include a first scanning line 106a, a second scanning line 106b, and a signal line 107.

The light emitting element 201, the driving transistor 202, the write transistor 203, the first capacitive element 702, and the second capacitive element 703 can be arranged in a first substrate 11. The first scanning line 106a, the signal line 107, and the Vss 205 can be arranged in a first wiring structure 512. From another viewpoint, the light emitting element 201, the driving transistor 202, the write transistor 203, the first capacitive element 702, the second capacitive element 703, the first scanning line 106a, the signal line 107, and the Vss 205 can be arranged in the first structure formed from the first substrate 11 and the first wiring structure 512. The light emission control transistor 701 can be arranged in a second substrate 12, and the second scanning line 106b and the Vdd 204 can be arranged in a second wiring structure 522. From another viewpoint, the light emission control transistor 701, the second scanning line 106b, and the Vdd 204 can be arranged in the second structure formed from the second substrate 12 and the second wiring structure 522. The source of the light emission control transistor 701 arranged in the second substrate 12 and the second capacitive element 703 arranged in the first substrate 11 can electrically be connected via bonding such as Cu—Cu bonding. The drain of the light emission control transistor 701 arranged in the second substrate 12 and the source of the driving transistor 202 arranged in the first substrate 11 can electrically be connected via bonding such as Cu—Cu bonding.

One (the source in this example) of the source and drain of the light emission control transistor 701 can be connected to one (the drain in this example) of the source and drain of the driving transistor 202. The other of the source and drain of the light emission control transistor 701 can be connected to the Vdd 204. The gate of the write transistor 203 can be connected to the first scanning line 106a. The gate of the light emission control transistor 701 can be connected to the second scanning line 106b. The first capacitive element 702 is arranged to electrically connect the gate and source (the connection node of the driving transistor 202 and the light emission control transistor 701) of the driving transistor 202. The second capacitive element 703 can be arranged to electrically connect the source of the driving transistor 202 to the Vdd 204. The first capacitive element 702 and the second capacitive element 703 have a function of holding the voltage between the source and the gate of the driving transistor 202. Each of the first capacitive element 702 and the second capacitive element 703 can be formed by a parasitic capacitance or a MIM structure.

The light emission control transistor 701 is rendered conductive, thereby making it possible to supply a current from the Vdd 204 to the driving transistor 202. This causes the driving transistor 202 to drive the light emitting element 201 to emit light. That is, the light emission control transistor 701 functions as a transistor that controls light emission/non-light emission of the light emitting element 201.

In the third embodiment, the light emitting element 201, the driving transistor 202, the write transistor 203, the first scanning line 106a, the signal line 107, the Vss 205, the first capacitive element 702, and the second capacitive element 703 are arranged in the first structure formed from the first substrate 11 and the first wiring structure 512. The light emission control transistor 701, the second scanning line 106b, and the Vdd 204 are arranged in the second structure formed from the second substrate 12 and the second wiring structure 522. This can reduce an area occupied by the transistor in each of the first substrate 11 and the second substrate 12. Therefore, the light emitting device 101 according to the third embodiment is advantageous in arranging the light emitting elements at a high density without reducing the size of each transistor. Furthermore, the third embodiment is advantageous in increasing the resolution when the light emitting device 101 is implemented as a display device.

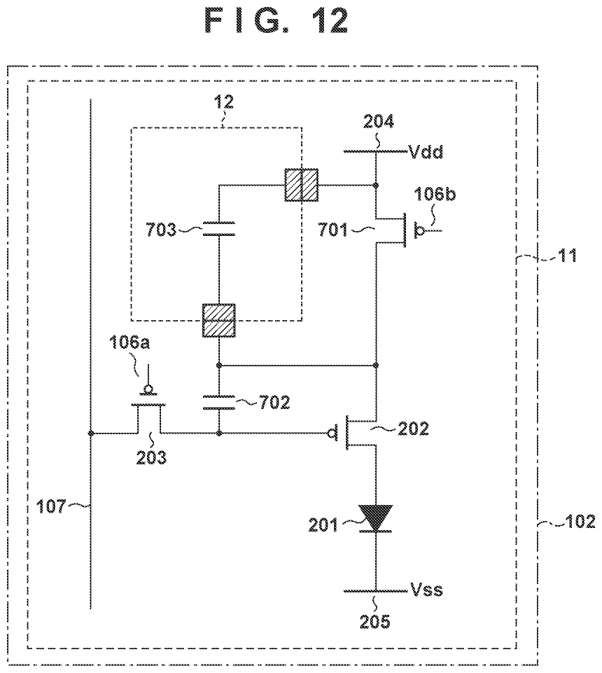

FIG. 12 exemplifies the circuit arrangement of one pixel 102 of a light emitting device 101 according to the fourth embodiment. Matters not mentioned in the fourth embodiment can comply with the third embodiment. In the fourth embodiment, a light emitting element 201 can be arranged on a second surface S2 of a first substrate 11, and a driving transistor 202, a write transistor 203, and a light emission control transistor 701 can be arranged in the first substrate 11. A first scanning line 106a, a second scanning line 106b, a signal line 107, a Vdd 204, and a Vss 205 can be arranged in a first wiring structure 512. From another viewpoint, the light emitting element 201, the driving transistor 202, the write transistor 203, and the light emission control transistor 701 can be arranged in the first structure formed from the first substrate 11 and the first wiring structure 512. The first scanning line 106a, the second scanning line 106b, the signal line 107, the Vdd 204, the Vss 205, and a first capacitive element 702 can be arranged in the first structure formed from the first substrate 11 and the first wiring structure 512. A second capacitive element 703 can be arranged in a second substrate 12.

According to the fourth embodiment, since the second capacitive element 703 is arranged in the second substrate 12, an area occupied by the element in each of the first substrate 11 and the second substrate 12 can be decreased. Therefore, the light emitting device 101 according to the fourth embodiment is advantageous in arranging the light emitting elements at a high density without reducing the size of each transistor. Furthermore, the fourth embodiment is advantageous in increasing the resolution when the light emitting device 101 is implemented as a display device.

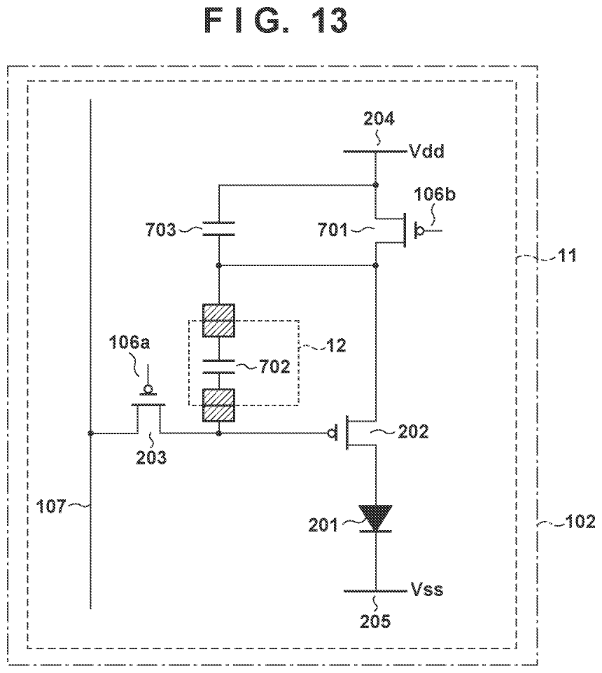

FIG. 13 exemplifies the circuit arrangement of one pixel 102 of a light emitting device 101 according to the fifth embodiment. Matters not mentioned in the fifth embodiment can comply with the third embodiment. In the fifth embodiment, a light emitting element 201, a driving transistor 202, a write transistor 203, a light emission control transistor 701, and a second capacitive element 703 can be arranged in a first substrate 11. In the fifth embodiment, a first scanning line 106a, a second scanning line 106b, a signal line 107, a Vdd 204, and a Vss 205 can be arranged in a first wiring structure 512. In the fifth embodiment, a first capacitive element 702 can be arranged in a second substrate 12. Therefore, the light emitting device 101 according to the fifth embodiment is advantageous in arranging the light emitting elements at a high density without reducing the size of each transistor. Furthermore, the fifth embodiment is advantageous in increasing the resolution when the light emitting device 101 is implemented as a display device.

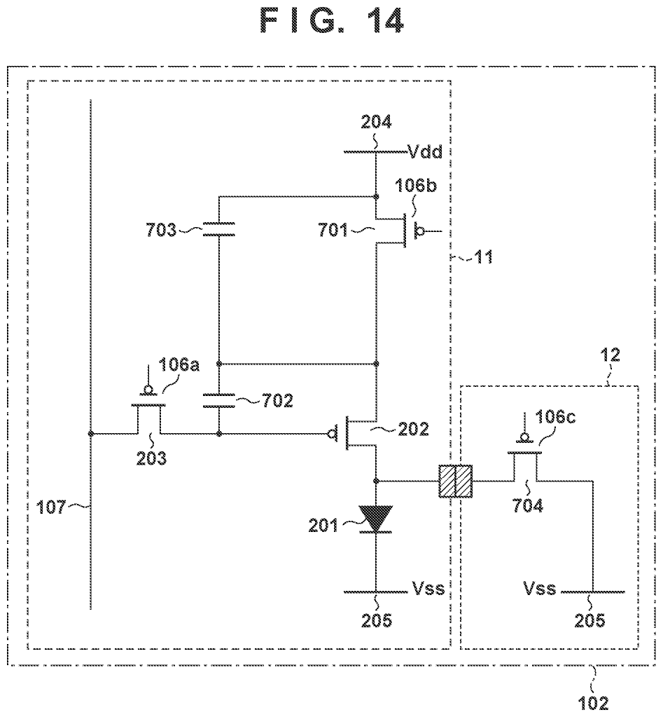

FIG. 14 exemplifies the circuit arrangement of one pixel 102 of a light emitting device 101 according to the sixth embodiment. Matters not mentioned in the sixth embodiment can comply with the third embodiment. In the sixth embodiment, each pixel 102 can include a light emitting element 201, a driving transistor 202, a write transistor 203, a Vdd 204, a Vss 205, a light emission control transistor 701, a first capacitive element 702, and a second capacitive element 703. Each pixel 102 can further include a reset transistor 704, a first scanning line 106a, a second scanning line 106b, a third scanning line 106c, and a signal line 107. The light emitting element 201, the driving transistor 202, the write transistor 203, the light emission control transistor 701, the first capacitive element 702, and the second capacitive element 703 can be arranged in a first substrate 11. The first scanning line 106a, the second scanning line 106b, and the signal line 107 can be arranged in a first wiring structure 512. The reset transistor 704 can be arranged in a second substrate 12, and the third scanning line 106c can be arranged in a second wiring structure 522.

One (the source in FIG. 14) of the source and drain of the reset transistor 704 can electrically be connected to one (the drain in this example) of the source and drain of the driving transistor 202 via bonding such as Cu—Cu bonding. The other of the source and drain of the reset transistor 704 can electrically be connected to the Vss 205. The gate of the reset transistor 704 can electrically be connected to the third scanning line 106c. The reset transistor 704 is rendered conductive to reset the voltage of the anode of the light emitting element 201 to the potential of the Vss. That is, the reset transistor 704 functions as a transistor that controls light emission/non-light emission of the light emitting element 201.

As described above, according to the sixth embodiment, the light emitting element 201, the driving transistor 202, the write transistor 203, the light emission control transistor 701, the first capacitive element 702, and the second capacitive element 703 can be arranged in the first substrate 11. The first scanning line 106a, the second scanning line 106b, the signal line 107, the Vdd 204, and the Vss 205 can be arranged in the first wiring structure 512. Furthermore, the reset transistor 704 can be arranged in the second substrate 12, and the third scanning line 106c and the Vss 205 can be arranged in the second wiring structure 522. This can reduce an area occupied by the element in each of the first substrate 11 and the second substrate 12. Therefore, the light emitting device 101 according to the sixth embodiment is advantageous in arranging the light emitting elements at a high density without reducing the size of each transistor. Furthermore, the sixth embodiment is advantageous in increasing the resolution when the light emitting device 101 is implemented as a display device.

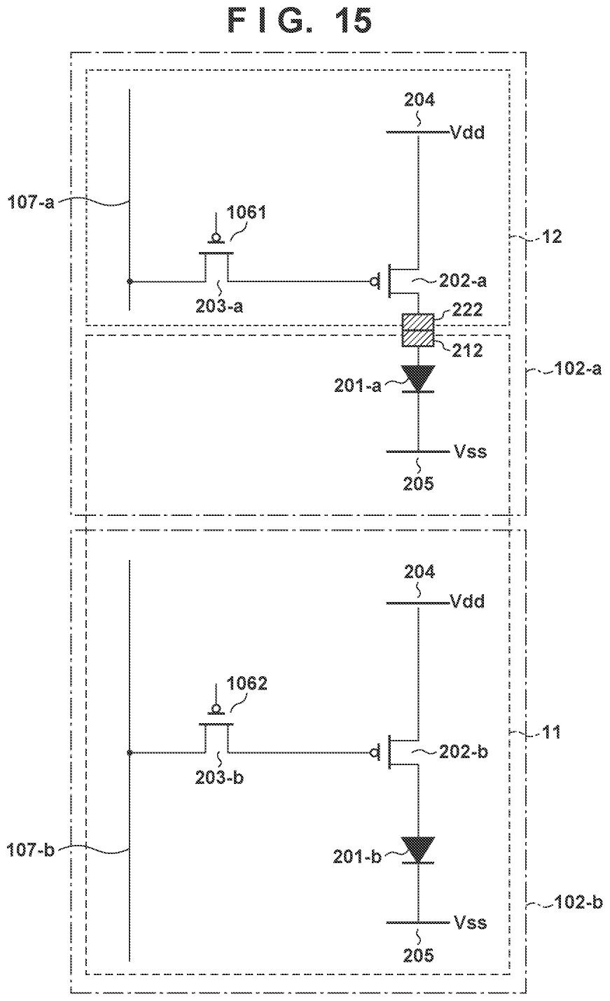

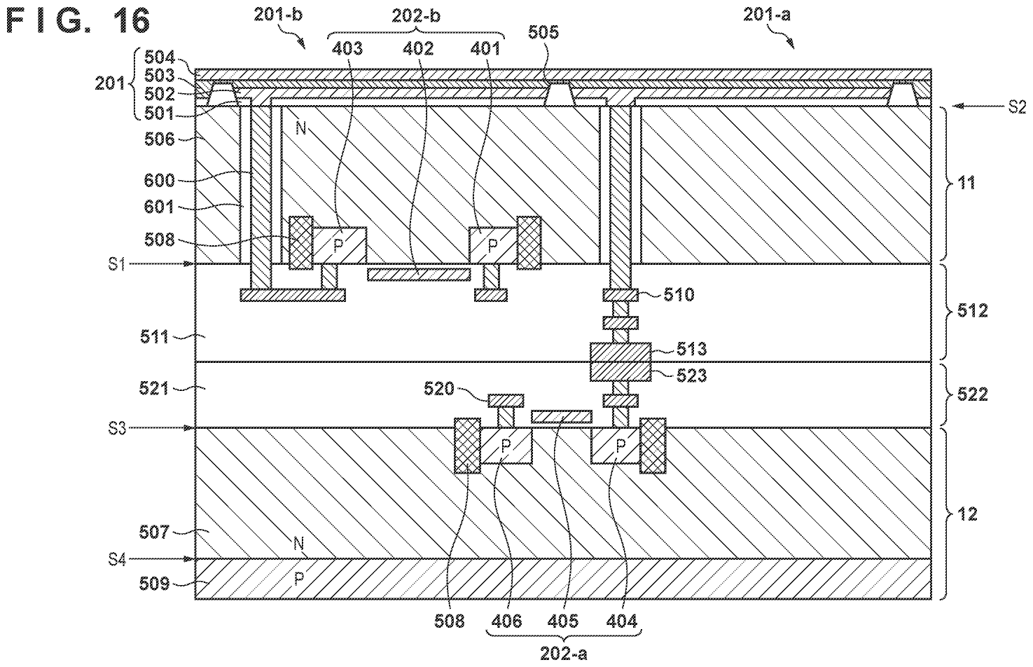

FIG. 15 exemplifies the circuit arrangement of one pixel 102 of a light emitting device 101 according to the seventh embodiment. FIG. 16 exemplifies the sectional structure of the pixel 102 of the light emitting device 101 according to the seventh embodiment. Matters not mentioned in the seventh embodiment can comply with one of the first to sixth embodiments and their modifications. For the sake of convenience, two pixels 102-a and 102-b will be described below. The pixel 102-a exemplifies the first type of pixel and the pixel 102-b exemplifies the second type of pixel. Alternatively, the pixel 102-b exemplifies the first type of pixel and the pixel 102-a exemplifies the second type of pixel. The first type of light emitting element and the second type of light emitting element are configured to express different colors. The first type of light emitting element and the second type of light emitting element can be configured to express different colors by having color filters of different colors. Alternatively, the first type of light emitting element and the second type of light emitting element can be configured to express different colors by emitting light beams in bands for which organic layers are different from each other. The first type of light emitting element and the second type of light emitting element can be arranged adjacent to each other.

As described above, each of the plurality of pixels 102 forming a pixel array 103 can include a light emitting element 201 and a plurality of elements for driving the light emitting element 201. The plurality of elements of each pixel 102 can form a unit driving circuit. It can be understood that an aggregate of the plurality of elements of the plurality of pixels 102 forming the pixel array 103 forms a driving circuit that drives the plurality of light emitting elements 201 of the pixel array 103. It may be understood that the plurality of light emitting elements 201 include a plurality of light emitting elements of the first type and a plurality of light emitting elements of the second type. It may be understood that the driving circuit which drives the plurality of light emitting elements 201 of the pixel array 103 includes a plurality of first driving circuits that drive the plurality of light emitting elements of the first type, respectively, and a plurality of second driving circuits that drive the plurality of light emitting elements of the second type, respectively. At least part of each of the plurality of first driving circuits can be arranged in a second substrate 12, and at least part of each of the plurality of second driving circuits can be arranged in a first substrate 11.

The first pixel 102-a includes a first type of light emitting element 201-a, a Vss 205, a driving transistor 202-a, a write transistor 203-a, a first scanning line 1061, a signal line 107-a, and a Vdd 204. The driving transistor 202-a and the write transistor 203-a form the first driving circuit that drives the first type of light emitting element 201-a. The first type of light emitting element 201-a is arranged on a second surface S2 of the first substrate 11, and the Vss 205 is arranged in a first wiring structure 512. From another viewpoint, the first type of light emitting element 201-a and the Vss 205 are arranged in the first structure formed from the first substrate 11 and the first wiring structure 512. The driving transistor 202-a and the write transistor 203-a can be arranged in the second substrate 12, and the first scanning line 1061, the signal line 107-a, and the Vdd 204 can be arranged in a second wiring structure 522. From another viewpoint, the driving transistor 202-a, the write transistor 203-a, the first scanning line 1061, the signal line 107-a, and the Vdd 204 can be arranged in the second structure formed from the second substrate 12 and the second wiring structure 522. It may be understood that the driving transistor 202-a is a transistor that decides the luminance of the light emitting element 201-a, a transistor that controls a current flowing through the light emitting element 201-a, or a transistor that is directly connected to the electrode of the light emitting element 201-a.

The second pixel 102-b includes a second type of light emitting element 201-b, a Vss 205, a driving transistor 202-b, a write transistor 203-b, a second scanning line 1062, a signal line 107-b, and a Vdd 204. The driving transistor 202-b and the write transistor 203-b form the second driving circuit that drives the second type of light emitting element 201-b. The second type of light emitting element 201-b can be arranged on the second surface S2 of the first substrate 11, and the driving transistor 202-b and the write transistor 203-b can be arranged in the second substrate 12. The Vss 205, the first scanning line 1061, the signal line 107-b, and the Vdd 204 can be arranged in the first wiring structure 512. From another viewpoint, the second type of light emitting element 201-b, the Vss 205, the driving transistor 202-b, the write transistor 203-b, the second scanning line 1062, the signal line 107-b, and the Vdd 204 can be arranged in the first structure formed from the first substrate 11 and the first wiring structure 512. It may be understood that the driving transistor 202-b is a transistor that decides the luminance of the light emitting element 201-b, a transistor that controls a current flowing through the light emitting element 201-b, or a transistor that is directly connected to the electrode of the light emitting element 201-b.

An n-type well layer 506 can be arranged in the first substrate 11. Part of each of the driving transistor 202-b and the write transistor 203-b is arranged between the first substrate 11 and the first wiring structure 512. Note that FIG. 16 does not illustrate the write transistor 203-b. P-type diffusion regions 401 and 403 of the driving transistor 202-b are arranged in the first substrate 11, and a gate 402 of the driving transistor 202-b is arranged on the first surface S1 of the first substrate 11 via a gate insulating film. The driving transistor 202-b and the write transistor 203-b can be formed by, for example, a general CMOS process.

An n-type well layer 507 and a p-type semiconductor layer 509 can be arranged in the second substrate 12. Part of each of the driving transistor 202-a and the write transistor 203-a is arranged between the second substrate 12 and the second wiring structure 522. Note that FIG. 16 does not illustrate the write transistor 203-a. P-type diffusion regions 404 and 406 of the driving transistor 202-a are arranged in the second substrate 12, and a gate 405 of the driving transistor 202-a is arranged on the third surface S3 of the second substrate 12 via a gate insulating film. The driving transistor 202-a and the write transistor 203-a can be formed by, for example, a general CMOS process. The p-type diffusion regions 401 and 403 of the first substrate 11 may be different from the p-type diffusion regions 404 and 406 of the second substrate 12 in at least one of the density and the depth.

As described above, according to the seventh embodiment, the first pixel 102-a includes the first driving circuit that drives the first type of light emitting element 201-a, and at least part of the first driving circuit is arranged in the second substrate 12. Furthermore, according to the seventh embodiment, the second pixel 102-b includes the second driving circuit that drives the second type of light emitting element 201-b, and at least part of the second driving circuit is arranged in the first substrate 11. This can reduce an area occupied by the element in each of the first substrate 11 and the second substrate 12. Therefore, the light emitting device 101 according to the seventh embodiment is advantageous in arranging the light emitting elements at a high density without reducing the size of each transistor. Furthermore, the seventh embodiment is advantageous in increasing the resolution when the light emitting device 101 is implemented as a display device.

Application examples of the above-described light emitting device 101 will be described below.

The above-described light emitting device 101 can be used as a constituent member of a display device or an illumination device. In addition, the light emitting device 101 is applicable to the exposure light source of an electrophotographic image forming device, the backlight of a liquid crystal display device, a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

A display device according to one application example will be described next with reference to the accompanying drawings.

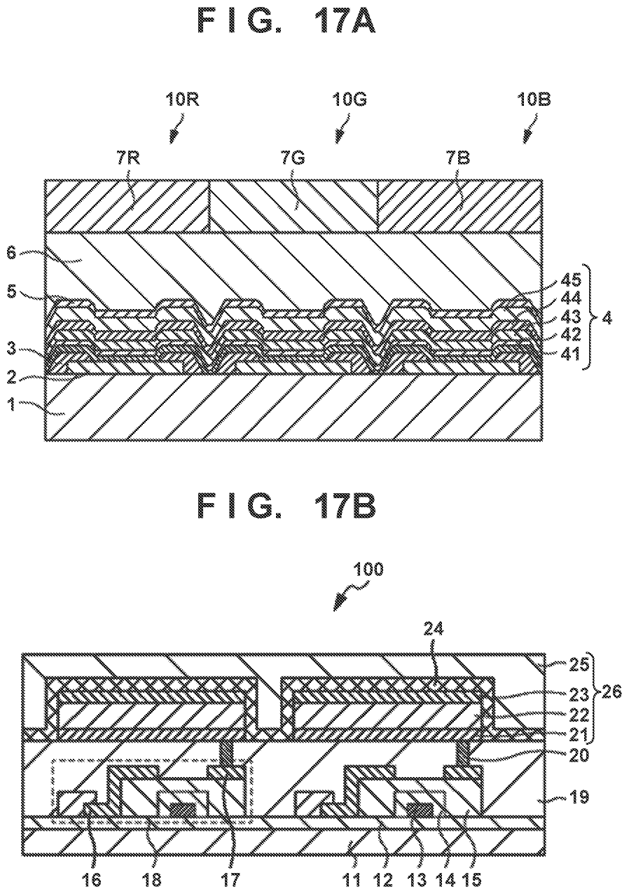

FIGS. 17A and 17B are schematic sectional views showing an example of a display device including an organic light emitting element and a transistor connected to it. The transistor is an example of an active element. The transistor may be a thin-film transistor (TFT).

FIG. 17A shows an example of a pixel as a constituent element of the display device according to one application example. The pixel includes sub-pixels 10. The sub-pixels are divided into sub-pixels 10R, 10G, and 10B by emitted light components. The light emission colors may be discriminated by wavelengths of light components emitted from the light emitting layers, or light emitted from each sub-pixel may be selectively transmitted or undergo color conversion by a color filter or the like. Each sub-pixel includes a reflective electrode 2 as the first electrode on an interlayer insulating layer 1, an insulating layer 3 covering the end of the reflective electrode 2, an organic compound layer 4 covering the first electrode and the insulating layer, a transparent electrode 5, a protection layer 6, and a color filter 7.

The interlayer insulating layer 1 can include a transistor and a capacitive element arranged in the interlayer insulating layer 1 or a layer below it. The transistor and the first electrode can electrically be connected via a contact hole (not shown) or the like.

The insulating layer 3 is also called a bank or a pixel separation film. The insulating layer 3 covers the end of the first electrode, and is arranged to surround the first electrode. A portion where no insulating layer is arranged contacts the organic compound layer 4 to form a light emission region.

The organic compound layer 4 includes a hole injection layer 41, a hole transport layer 42, a first light emitting layer 43, a second light emitting layer 44, and an electron transport layer 45.

The second electrode 5 may be a transparent electrode, a reflective electrode, or a translucent electrode.

The protection layer 6 suppresses permeation of water into the organic compound layer. The protection layer is shown as a single layer but may include a plurality of layers. Each layer can be an inorganic compound layer or an organic compound layer.

The color filter 7 is divided into color filters 7R, 7G, and 7B by colors. The color filters can be formed on the planarizing layer (not shown). A resin protection layer (not shown) can be provided on the color filters. The color filters can be formed on the protection layer 6. Alternatively, the color filters can be provided on the counter substrate such as a glass substrate, and then the substrate may be bonded.

A display device 100 shown in FIG. 17B is provided with an organic light emitting element 26 and a TFT 18 as an example of a transistor. A substrate 11 of glass, silicon, or the like is provided and an insulating layer 12 is provided on the substrate 11. The active element 18 such as a TFT is arranged on the insulating layer, and a gate electrode 13, a gate insulating film 14, and a semiconductor layer 15 of the active element are arranged. The TFT 18 further includes the semiconductor layer 15, a drain electrode 16, and a source electrode 17. An insulating film 19 is provided on the TFT 18. The source electrode 17 and an anode 21 forming the organic light emitting element 26 are connected via a contact hole 20 formed in the insulating film.

Note that a method of electrically connecting the electrodes (anode and cathode) included in the organic light emitting element 26 and the electrodes (source electrode and drain electrode) included in the TFT is not limited to that shown in FIG. 17B. That is, one of the anode and cathode and one of the source electrode and drain electrode of the TFT are electrically connected. The TFT indicates a thin-film transistor.

In the display device 100 shown in FIG. 17B, an organic compound layer is illustrated as one layer. However, an organic compound layer 22 may include a plurality of layers. A first protection layer 24 and a second protection layer 25 are provided on a cathode 23 to suppress the degradation of the organic light emitting element.

A transistor is used as a switching element in the display device 100 shown in FIG. 17B but may be used as another switching element.

The transistor used in the display device 100 shown in FIG. 17B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 100 shown in FIG. 17B may be formed in the substrate such as an Si substrate. Forming the transistor in the substrate means forming the transistor by processing the substrate such as an Si substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Note that the switching element according to this embodiment is not limited to the TFT, and may be a transistor formed from low-temperature polysilicon or an active matrix driver formed on the substrate such as an Si substrate. The term “on the substrate” may mean “in the substrate”. Whether to provide a transistor in the substrate or use a TFT is selected based on the size of the display unit. For example, if the size is about 0.5 inch, the organic light emitting element is preferably provided on the Si substrate.

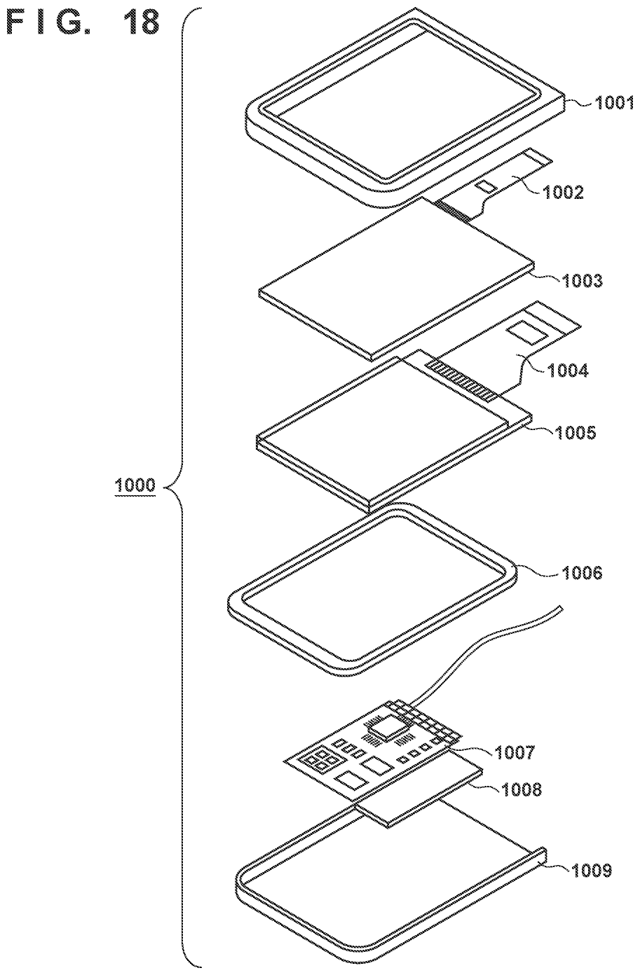

FIG. 18 is a schematic view showing an example of a display device according to one application example. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Transistors are printed on the circuit board 1007. The battery 1008 is unnecessary if the display device is not a portable equipment. Even when the display device is a portable equipment, the battery 1008 may be arranged at another position.

The display device can include color filters of red, green, and blue. The color filters of red, green, and blue can be arranged in a delta array.

The display device can also be used for a display unit of a portable terminal. At this time, the display unit can have both a display function and an operation function. Examples of the portable terminal are a portable phone such as a smartphone, a tablet, and a head mounted display.

The display device can be used for a display unit of an image capturing device including an optical unit having a plurality of lenses, and an image sensor for receiving light having passed through the optical unit. The image capturing device can include a display unit for displaying information acquired by the image sensor. In addition, the display unit can be either a display unit exposed outside the image capturing device, or a display unit arranged in the finder. The image capturing device can be a digital camera or a digital video camera.

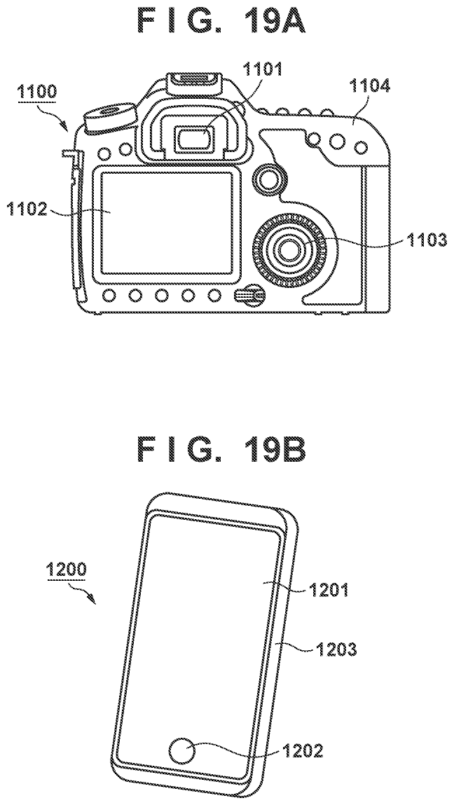

FIG. 19A is a schematic view showing an example of an image capturing device according to one application example. An image capturing device 1100 can include a viewfinder 1101, a rear display 1102, an operation unit 1103, and a housing 1104. The viewfinder 1101 can include the display device according to this embodiment. In this case, the display device can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time, so the information is preferably displayed as soon as possible. Therefore, the display device using the organic light emitting element of the present invention is preferably used. This is so because the organic light emitting element has a high response speed. The display device using the organic light emitting element can be used for the apparatuses that require a high display speed more preferably than for the liquid crystal display device.

The image capturing device 1100 includes an optical unit (not shown). This optical unit has a plurality of lenses, and forms an image on an image sensor that is accommodated in the housing 1104. The focal points of the plurality of lenses can be adjusted by adjusting the relative positions. This operation can also automatically be performed. The image capturing device may be called a photoelectric conversion device. Instead of sequentially capturing an image, the photoelectric conversion device can include, as an image capturing method, a method of detecting the difference from a previous image, a method of extracting an image from an always recorded image, or the like.

FIG. 19B is a schematic view showing an example of an electronic equipment according to one application example. An electronic equipment 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit can also be a biometric authentication unit that performs unlocking or the like by authenticating the fingerprint. The electronic equipment including the communication unit can also be regarded as a communication equipment. The electronic equipment can further have a camera function by including a lens and an image sensor. An image captured by the camera function is displayed on the display unit. Examples of the electronic equipment are a smartphone and a notebook computer.

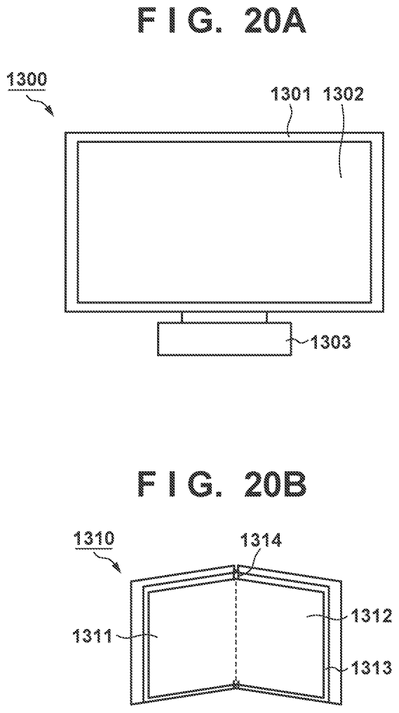

FIG. 20A is a schematic view showing an example of a display device according to one application example. FIG. 20A shows a display device such as a television monitor or a PC monitor. A display device 1300 includes a frame 1301 and a display unit 1302. The light emitting device according to this embodiment can be used for the display unit 1302.

The display device 1300 includes a base 1303 that supports the frame 1301 and the display unit 1302. The base 1303 is not limited to the form shown in FIG. 20A. The lower side of the frame 1301 may also function as the base.

In addition, the frame 1301 and the display unit 1302 can be bent. The radius of curvature in this case can be 5,000 (inclusive) mm to 6,000 (inclusive) mm.

FIG. 20B is a schematic view showing a display device according to one application example. A display device 1310 shown in FIG. 20B can be folded, that is, the display device 1310 is a so-called foldable display device. The display device 1310 includes a first display unit 1311, a second display unit 1312, a housing 1313, and a bending point 1314. Each of the first display unit 1311 and the second display unit 1312 can include the light emitting device according to this embodiment. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

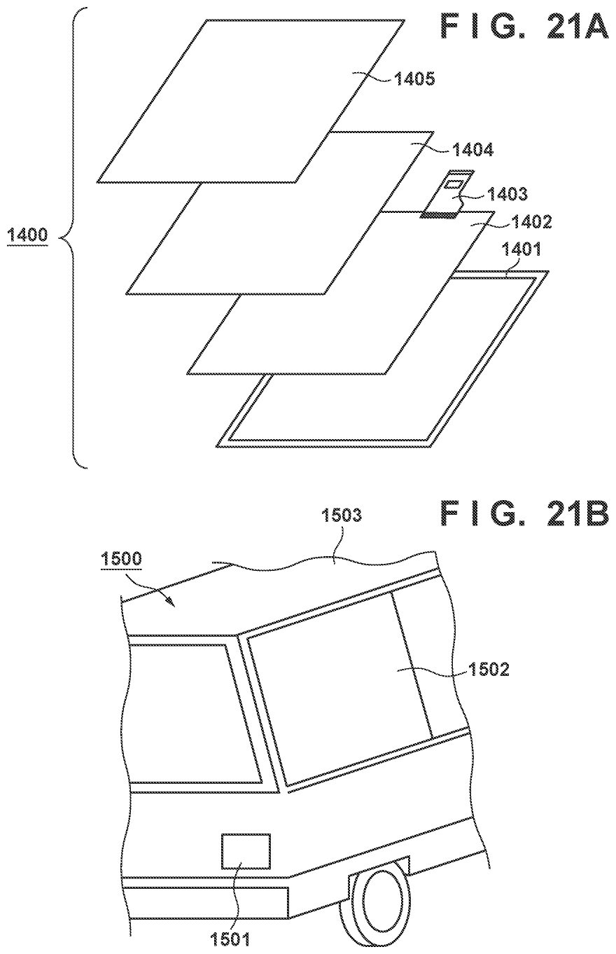

FIG. 21A is a schematic view showing an example of an illumination device according to one application example. An illumination device 1400 can include a housing 1401, a light source 1402, a circuit board 1403, an optical film 1404, and a light-diffusing unit 1405. The light source can include the organic light emitting element according to this embodiment. The optical film can be a filter that improves the color rendering of the light source. When performing lighting-up or the like, the light-diffusing unit can throw the light of the light source over a broad range by effectively diffusing the light. The optical film and the light-diffusing unit can be provided on the illumination light emission side. The illumination device can also include a cover on the outermost portion, as needed.

The illumination device is, for example, a device for illuminating the interior of the room. The illumination device can emit white light, natural white light, or light of any color from blue to red. The illumination device can also include a light control circuit for controlling these light components. The illumination device can also include the organic light emitting element according to the present invention and a power supply circuit connected to the organic light emitting element. The power supply circuit is a circuit for converting an AC voltage into a DC voltage. White has a color temperature of 4,200 K, and natural white has a color temperature of 5,000 K. The illumination device may also include a color filter.

In addition, the illumination device according to this embodiment can include a heat radiation unit. The heat radiation unit radiates the internal heat of the device to the outside of the device, and examples are a metal having a high specific heat and liquid silicon.

FIG. 21B is a schematic view of an automobile as an example of a moving body according to one application example. The automobile has a taillight as an example of the lighting appliance. An automobile 1500 has a taillight 1501, and can have a form in which the taillight is turned on when performing a braking operation or the like.

The taillight 1501 can include the organic light emitting element according to this embodiment. The taillight can include a protection member for protecting the organic EL element. The material of the protection member is not limited as long as the material is a transparent material with a strength that is high to some extent, and is preferably polycarbonate. A furandicarboxylic acid derivative, an acrylonitrile derivative, or the like may be mixed in polycarbonate.

The automobile 1500 can include a vehicle body 1503, and a window 1502 attached to the vehicle body 1503. This window can be a window for checking the front and back of the automobile, and can also be a transparent display. This transparent display can include the organic light emitting element according to this embodiment. In this case, the constituent materials of the electrodes and the like of the organic light emitting element are preferably formed by transparent members.

The moving body according to this embodiment can be a ship, an airplane, a drone, or the like. The moving body can include a main body and a lighting appliance installed in the main body. The lighting appliance can emit light for making a notification of the position of the main body. The lighting appliance includes the organic light emitting element according to this embodiment.

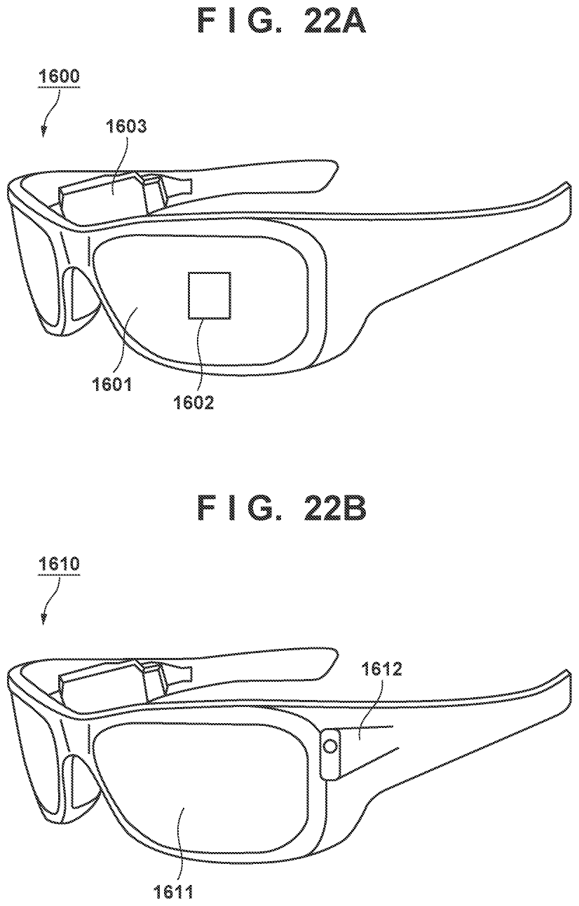

Application examples of a display device will be described with reference to FIGS. 22A and 22B. The display device can be applied to a system that can be worn as a wearable device such as smartglasses, an HMD, or a smart contact lens. An image capturing display device used for such application examples can include an image capturing device capable of photoelectrically converting visible light and a display device capable of emitting visible light.

Glasses 1600 (smartglasses) according to one application example will be described with reference to FIG. 22A. An image capturing device 1602 such as a CMOS sensor or an SPAD is provided on the surface side of a lens 1601 of the glasses 1600. In addition, the display device of each of the above-described embodiments is provided on the back surface side of the lens 1601.

The glasses 1600 can further include a control device 1603. The control device 1603 functions as a power supply that supplies power to the image capturing device 1602 and the display device according to each embodiment. In addition, the control device 1603 controls the operations of the image capturing device 1602 and the display device. An optical system configured to condense light to the image capturing device 1602 is formed on the lens 1601.

Glasses 1610 (smartglasses) according to one application example will be described with reference to FIG. 22B. The glasses 1610 includes a control device 1612, and an image capturing device corresponding to the image capturing device 1602 and a display device are mounted on the control device 1612. The image capturing device in the control device 1612 and an optical system configured to project light emitted from the display device are formed in a lens 1611, and an image is projected to the lens 1611. The control device 1612 functions as a power supply that supplies power to the image capturing device and the display device, and controls the operations of the image capturing device and the display device. The control device may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The display device according to the embodiment of the present invention can include an image capturing device including a light receiving element, and a displayed image on the display device can be controlled based on the line-of-sight information of the user from the image capturing device.

More specifically, the display device can decide a first visual field region at which the user is gazing and a second visual field region other than the first visual field region based on the line-of-sight information. The first visual field region and the second visual field region may be decided by the control device of the display device, or those decided by an external control device may be received. In the display region of the display device, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the display device, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the display device, the image capturing device, or an external device. If the external device holds the AI program, it is transmitted to the display device via communication.

When performing display control based on line-of-sight detection, smartglasses further including an image capturing device configured to capture the outside can preferably be applied. The smartglasses can display captured outside information in real time.

As described above, when a device using the organic light emitting element according to this embodiment is used, stable display with high image quality can be performed even in long time display.

According to the present invention, there is provided a technique advantageous in increasing the density of light emitting elements.

### Other Embodiments

Embodiment(s) of the present invention can also be realized by a computer of a system or apparatus that reads out and executes computer executable instructions (e.g., one or more programs) recorded on a storage medium (which may also be referred to more fully as ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)?), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2021-131743, filed Aug. 12, 2021, which is hereby incorporated by reference herein in its entirety.

What is claimed is:

1. A light emitting device having a structure in which a first substrate and a second substrate are stacked, comprising:
a plurality of light emitting elements; and
a driving circuit configured to drive the plurality of light emitting elements,
wherein part of the driving circuit is arranged in the first substrate, and another part of the driving circuit is arranged in the second substrate.

2. The device according to claim 1, wherein
the driving circuit includes a plurality of unit driving circuits respectively configured to drive the plurality of light emitting elements,
each of the plurality of unit driving circuits includes a plurality of elements, and
the plurality of elements include a first element arranged in the first substrate and a second element arranged in the second substrate.

3. The device according to claim 2, wherein
the first substrate includes a first surface and a second surface which are opposing faces, and the second substrate includes a third surface and a fourth surface which are opposing faces,
a first wiring structure is arranged to contact the first surface, and a second wiring structure is arranged to contact the third surface,
the first wiring structure and the second wiring structure are connected to each other,
the plurality of light emitting elements are arranged on the second surface,
at least part of the first element is arranged between the first surface and the first wiring structure, and
at least part of the second element is arranged between the third surface and the second wiring structure.

4. The device according to claim 3, wherein a conductive path penetrating the first substrate to connect the first element to one of the plurality of light emitting elements is provided in the first substrate.

5. The device according to claim 4, wherein the first substrate has a through hole and the conductive path includes a conductive plug arranged in the through hole via an insulating film.

6. The device according to claim 4, wherein the conductive path includes an impurity semiconductor region arranged to penetrate the first substrate.

7. The device according to claim 6, wherein the impurity semiconductor region is surrounded by an insulating film.

8. The device according to claim 2, wherein
the plurality of light emitting elements are arranged to form a plurality of rows and a plurality of columns, and
a plurality of signal lines extending in a column direction are provided for each column.

9. The device according to claim 2, wherein
the first element is a driving transistor configured to drive one of the plurality of light emitting elements, and
the second element is a write transistor configured to write a signal in a write node including a gate of the driving transistor.

10. The device according to claim 2, wherein
the second element is a driving transistor configured to drive one of the plurality of light emitting elements, and
the first element is a write transistor configured to write a signal in a write node including a gate of the driving transistor.

11. The device according to claim 9, wherein a back gate of the driving transistor is self-biased.

12. The device according to claim 2, wherein the plurality of elements include a driving transistor configured to drive one of the plurality of light emitting elements, a write transistor configured to write a signal in a write node including a gate of the driving transistor, a light emission control transistor arranged to control connection between a voltage line and the driving transistor, a first capacitive element arranged to electrically connect the driving transistor to a connection node of the driving transistor and the light emission control transistor, and a second capacitive element arranged to electrically connect the connection node to the voltage line.

13. The device according to claim 12, wherein the second element is the light emission control transistor.

14. The device according to claim 12, wherein the second element is one of the first capacitive element and the second capacitive element.

15. The device according to claim 12, wherein
the plurality of elements further include a reset transistor configured to reset a potential of a connection node of the driving transistor and one of the plurality of light emitting elements, and
the second element is the reset transistor.

16. The device according to claim 1, wherein
the plurality of light emitting elements include a plurality of light emitting elements of a first type and a plurality of light emitting elements of a second type,
the driving circuit includes a plurality of first driving circuits respectively configured to drive the plurality of light emitting elements of the first type, and a plurality of second driving circuits respectively configured to drive the plurality of light emitting elements of the second type, and
at least part of each of the plurality of first driving circuits is arranged in the second substrate and at least part of each of the plurality of second driving circuits is arranged in the first substrate.

17. The device according to claim 16, wherein the first type of light emitting element and the second type of light emitting element are configured to express different colors.

18. The device according to claim 16, wherein the first type of light emitting element and the second type of light emitting element are arranged adjacent to each other.

19. The device according to claim 16, wherein each of the plurality of first driving circuits includes a transistor arranged in the second substrate, and each of the plurality of second driving circuits includes a transistor arranged in the first substrate.

20. The device according to claim 16, wherein each of the plurality of first driving circuits includes a driving transistor arranged in the second substrate and configured to drive one of the plurality of light emitting elements of the first type, and each of the plurality of second driving circuits includes a driving transistor arranged in the first substrate and configured to drive one of the plurality of light emitting elements of the second type.

21. The device according to claim 1, wherein the light emitting device is configured as a display device.

22. A photoelectric conversion device comprising:
an image sensor configured to receive light having passed through an optical unit; and
a display unit configured to display an image captured by the image sensor,
wherein the display unit includes a light emitting device defined in claim 1.

23. An electronic equipment comprising:
a light emitting device defined in claim 1;
a housing provided with the light emitting device; and
a communication unit provided in the housing and configured to perform external communication.

24. An illumination device comprising:
a light emitting device defined in claim 1; and
one of a light-diffusing unit and an optical film configured to transmit light emitted by the light emitting device.

25. A moving body comprising:
a lighting appliance including a light emitting device defined in claim 1; and
a main body provided with the lighting appliance.
